(19) United States
(12) Patent Application Publication
(10) Pub. No.: US 2019/0276948 A1
(43) Pub. Date: Sep. 12, 2019

(54) NANOSCALE METAL NANOWIRE AND THE FABRICATION METHOD OF THE SAME

(71) Applicant: KOREA UNIVERSITY RESEARCH AND BUSINESS FOUNDATION, Seoul (KR)

(72) Inventors: YoungKeun KIM, Seoul (KR); SuHyo KIM, Seoul (KR); MinJun KO, Seoul (KR)

(21) Appl. No.: 15/970,476

(22) Filed: May 3, 2018

(30) Foreign Application Priority Data
Mar. 12, 2018 (KR) 10-2018-0028762

(51) Int. Cl. C30B 7/12; C30B 29/10; C30B 29/60; C25D 1/00; C25D 1/04; C25D 3/12

(52) U.S. Cl. CPC C30B 7/12; C30B 29/10; C25D 3/12; C25D 1/006; C25D 1/04; C30B 29/60

(57) ABSTRACT

A fabrication method of a nickel nanowire includes: preparing an anodized aluminum oxide or plastic nanotemplate having nanopores and one surface on which platinum (Pt), palladium (Pd), gold (Au), silver (Ag), copper (Cu) or an alloy thereof is deposited as a working electrode; producing a plating solution which is a mixture of nickel(II) sulfate heptahydrate (NiSO₄.7H₂O) as a precursor and ammonium sulfate ((NH₄)₂SO₄) as a buffer solution; and dipping the anodized aluminum oxide or plastic nanotemplate into the plating solution and depositing a nickel nanowire in an electrodeposition process using platinum (Pt) or iridium (Ir) as a counter electrode. A crystal direction of the nickel nanowire is a [111] direction.

### CROSS-REFERENCE TO RELATED APPLICATIONS

This U.S. non-provisional patent application claims priority under 35 U.S.C. § 119 to Korean Patent Application No. 10-2018-0028762, filed on Mar. 12, 2018, in the Korean Intellectual Property Office, the entire contents of which are hereby incorporated by reference.

### TECHNICAL FIELD

The present disclosure relates to a fabrication method of a nickel nanowire which is capable of controlling preferred orientations during electrodeposition according to a combination of a precursor and a buffer solution and controlling an electrodeposition solution temperature to control grain sizes. More specifically, the present disclosure relates to a fabrication method of a nanowire which is capable of controlling crystal orientations and grain sizes using a template having nanopores or micropores in a single plating bath through template-based electrodeposition using a template.

### BACKGROUND

Until now, there have been conducted studies using characteristics of nanostructures having various shapes such as nanoparticles, nanowires, and nanotubes.

A nanowire structure having magnetic properties may be applied to magnetic sensors, drug delivery systems, diagnostic apparatuses, and the like.

Thermal plasma chemical vapor deposition (CVD), atomic layer deposition (ALD), hydrothermal method, laser deposition, etc. have been mainly used as a fabrication method of a nanowire structure. These methods use heat, pressure, and high voltage and are disadvantage in complex processes.

### SUMMARY

Example embodiments of the present disclosure provide a method for simply analyzing a nickel nanowire having desired electrical, magnetic or physical properties.

A fabrication method of a nickel nanowire according to an example embodiment of the present disclosure includes: preparing an anodized aluminum oxide or plastic nanotemplate having nanopores and one surface on which platinum (Pt), palladium (Pd), gold (Au), silver (Ag), copper (Cu) or an alloy thereof is deposited as a working electrode; producing a plating solution which is a mixture of nickel(II) sulfate heptahydrate (NiSO₄.7H₂O) as a precursor and ammonium sulfate ((NH₄)₂SO₄) as a buffer solution; and dipping the anodized aluminum oxide or plastic nanotemplate into the plating solution and depositing a nickel nanowire in an electrodeposition process using platinum (Pt) or iridium (Ir) as a counter electrode. A crystal direction of the nickel nanowire is a [111] direction.

In an example embodiment of the present disclosure, a concentration of the precursor may be between 1 mM and 50 M, a concentration of the buffer solution may be between 1 mM and 20 M, and a temperature of the plating solution may be between zero and 100 degrees Celsius.

A fabrication method of a nickel nanowire according to another example embodiment of the present disclosure includes: obtaining an anodized aluminum oxide or plastic nanotemplate having nanopores and one surface on which platinum (Pt), palladium (Pd), gold (Au), silver (Ag), copper (Cu) or an alloy thereof is deposited as a working electrode; producing a plating solution which is a mixture of nickel(II) sulfate heptahydrate (NiSO₄.7H₂O) as a precursor and boric acid H₃BO₃) as a buffer solution; and dipping the anodized aluminum oxide or plastic nanotemplate into the plating solution and depositing a nickel nanowire in an electrodeposition process using platinum (Pt) or iridium (Ir) as a counter electrode. A crystal direction of the nickel nanowire is a [200] direction.

In an example embodiment of the present disclosure, a concentration of the precursor may be between 1 mM and 50 M, a concentration of the buffer solution may be between 1 mM and 20 M, and a temperature of the plating solution may be between zero and 100 degrees Celsius.

A fabrication method of a nickel nanowire according to another example embodiment of the present disclosure includes: obtaining an anodized aluminum oxide or plastic nanotemplate having nanopores and one surface on which platinum (Pt), palladium (Pd), gold (Au), silver (Ag), copper (Cu) or an alloy thereof is deposited as a working electrode; producing a plating solution which is a mixture of nickel(II) chloride hexahydrate (NiCl₂.6H₂O) as a precursor and boric acid H₃BO₃) as a buffer solution; and dipping the anodized aluminum oxide or plastic nanotemplate into the plating solution and depositing a nickel nanowire in an electrodeposition process using platinum (Pt) or iridium (Ir) as a counter electrode. A crystal direction of the nickel nanowire may be a [220] direction.

In an example embodiment of the present disclosure, a concentration of the precursor may be between 1 mM and 50 M, a concentration of the buffer solution may be between 1 mM and 20 M, and a temperature of the plating solution may be between zero and 100 degrees Celsius.

In an example embodiment of the present disclosure, a mean diameter of the pore of the anodized aluminum oxide or plastic nanotemplate may be between 5 and 50 nm.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1A shows images of a scanning electron microscope of a nickel nanowire fabricated by means of electrodeposition according to an example embodiment of the present disclosure.

FIG. 1B shows a transmission electron microscope and a selected-area electron diffraction pattern of a nickel nanowire fabricated by means of electrodeposition according to an example embodiment of the present disclosure.

FIG. 2 shows a graph indicating X-ray diffraction (XRD) patterns of nickel nanowire arrays according to an example embodiment of the present disclosure.

FIG. 3 shows magnetization versus applied magnetic field curves of nickel nanowire arrays according to an example embodiment of the present disclosure.

FIG. 4 illustrates characteristics of a nickel nanowire array fabricated under various conditions.

FIG. 5 illustrates X-ray diffraction (XRD) results of a third nickel nanowire array (NiS-B) synthesized at temperatures of zero, 30, and 80 degrees Celsius, respectively.

FIG. 6 shows magnetization versus applied magnetic field curves of a third nickel nanowire array (NiS-B) synthesized at temperatures of zero, 30, and 80 degrees Celsius, respectively.

FIG. 7 shows an angle-dependent coercivity of a third nanowire (NiS-B).

### DETAILED DESCRIPTION

Electrodeposition suffers from a difficulty in controlling a microstructure of a polycrystalline metal nanowire. However, according to an example embodiment of the present application, in electrodeposition using an anodized aluminum nanotemplate that is one of nanowire synthesis methods, a microstructure is changed by adjusting a precursor and a buffer solution to adjust mechanical, electrical, and magnetic properties.

According to an example embodiment of the present disclosure, we synthesized a nickel nanowire array having different textures and grain sizes by variation of a precursor, a buffer solution, and a bath temperature during electrodeposition process.

Example embodiments will now be described more fully with reference to the accompanying drawings, in which some example embodiments are shown. Example embodiments may, however, be embodied in many different forms and should not be construed as being limited to the embodiments set forth herein; rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements, and thus their description may be omitted.

A fabrication method of a nickel nanowire according to an example embodiment of the present disclosure includes: preparing an anodized aluminum oxide or plastic nanotemplate having nanopores and one surface on which platinum (Pt), palladium (Pd), gold (Au), silver (Ag) or an alloy thereof are deposited as a working electrode; producing a plating solution which is a mixture of nickel(II) sulfate heptahydrate (NiSO₄.7H₂O) as a precursor and ammonium sulfate ((NH₄)₂SO₄) as a buffer solution; and dipping the anodized aluminum oxide or plastic nanotemplate into the plating solution and depositing a nickel nanowire in an electrodeposition process using platinum (Pt) or iridium (Ir) as a counter electrode. A crystal direction of the nickel nanowire is a [111] direction.

A nanoporous anodized aluminum oxide (AAO) nanotemplate having a constant diameter (ranging from tens of nanometers to hundreds of nanometers) is prepared. A silver (Ag) layer is deposited on one surface of the AAO nanotemplate to a thickness between 250 and 350 nanometers by an electron beam evaporator. The Ag layer deposited on a bottom surface of the AAO nanotemplate before electrodeposition is used as a working electrode during the electrodeposition. The working electrode may be platinum (Pt), palladium (Pd), gold (Au), silver (Ag), copper (Cu) or an alloy thereof.

The AAO nanotemplate is located in an electrodeposition bath. The electrodeposition cell is filled with a mixture of a nickel precursor and a buffer solution. The pH of the mixture was maintained within a range of 3 to 3.5. In an electrodeposition system, the Ag layer is used as a working electrode and platinum (Pt) or iridium (Ir) is used as a counter electrode. A direct current (DC) of a density of 10 mA/cm² was applied between the working electrode and the counter electrode. A temperature of the plating solution may be between zero and 80 degrees Celsius. A preferred orientation of the nickel nanowire may be controlled according to a composition of the plating solution used in the electrodeposition. A crystal direction may vary depending on the composition of the plating solution.

1. Synthesis of First Nickel Nanowires (NiS-As) Arranged in [111] Direction

A precursor may be nickel(II) sulfate heptahydrate (NiSO₄.7H₂O), and a buffer solution may be ammonium sulfate ((NH₄)₂SO₄). After the nickel(II) sulfate heptahydrate (NiSO₄.7H₂O) and the ammonium sulfate ((NH₄)₂SO₄) are mixed with each other, the mixture fills in anodized aluminum oxide (AAO) to synthesize a nickel nanowire. An aspect ratio of the first nickel nanowire (NiS-As) may be about 100.

A concentration of the precursor may be between 1 mM and 50 M, a concentration of the buffer solution may be between 1 mM and 20 M, and a temperature of the plating solution may be between zero and 100 degrees Celsius.

Preferably, the concentration of the precursor may be 0.5 M, the concentration of the buffer solution may be 0.2 M, and the temperature of the plating solution may between zero and 80 degrees Celsius.

2. Synthesis of Second Nickel Nanowires (NiCl-B) Arranged in [200] Direction

A precursor may be nickel(II) chloride hexahydrate (NiCl₂.6H₂O), and a buffer solution may be boric acid (H₃BO₃). After the nickel(II) chloride hexahydrate (NiCl₂.6H₂O) and the boric acid (H₃BO₃) are mixed with each other, the mixture fills in anodizing aluminum oxide (AAO) to synthesize a second nickel nanowire (NiCl-B).

A concentration of the precursor may be between 1 mM and 50 M, a concentration of the buffer solution may be between 1 mM and 20 M, and a temperature of the plating solution may be between zero and 100 degrees Celsius.

Preferably, the concentration of the precursor may be 0.5 M, the concentration of the buffer solution may be 0.2 M, and the temperature of the plating solution may be between zero and 80 degrees Celsius. An aspect ratio of the nickel nanowire is about 100.

3. Synthesis of Third Nickel Nanowires (NiS-B) Arranged in [220] Direction

A precursor may be nickel(II) sulfate heptahydrate (NiSO₄.7H₂O), and a buffer solution may be boric acid (H₃BO₃). After the nickel(II) sulfate heptahydrate (NiSO₄.7H₂O) and the boric acid (H₃BO₃) are mixed with each other, the mixture fills in anodized aluminum oxide (AAO) to synthesize a third nickel nanowire (NiS-B). A temperature of a plating bath is zero degree, 30 degrees, and 80 degrees Celsius depending on samples, respectively. An aspect ratio of the third nickel nanowire (NiS-B) is about 100.

A concentration of the precursor may be between 1 mM and 50 M, a concentration of the buffer solution may be between 1 mM and 20 M, and a temperature of the plating solution may be between zero and 100 degrees Celsius.

Preferably, the concentration of the precursor may be 0.5 M, the concentration of the buffer solution may be 0.2 M, and the temperature of the plating solution may be between zero and 80 degrees Celsius.

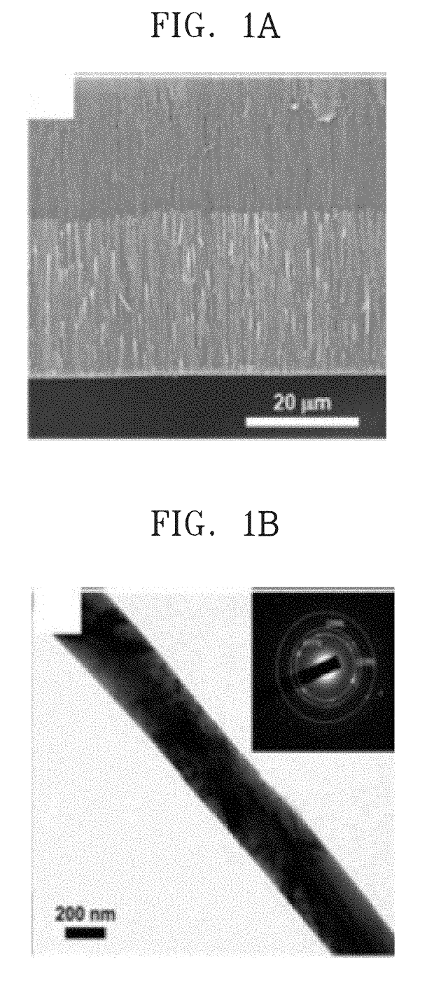

FIG. 1A shows images of a scanning electron microscope of a nickel nanowire fabricated by means of electrodeposition according to an example embodiment of the present disclosure.

FIG. 1B shows a transmission electron microscope and a selected-area electron diffraction pattern of a nickel nanowire fabricated by means of electrodeposition according to an example embodiment of the present disclosure.

Referring to FIG. 1A and FIG. 1B, first to third nanowire array samples are prepared to analyze the effect of a crystallographic direction for magnetic properties. A nickel nanowire array having different textures was fabricated under different plating solutions. The appearance of a nickel nanowire was checked using a scanning electron microscope (SEM) and a transmission electron microscope (TEM). An image of the third nickel nanowire (NiS-B) is shown in FIG. 1. A length of the third nanowire (NiS-B) is about 26 μm. A diameter of the third nanowire (NiS-B) is about 200 nm.

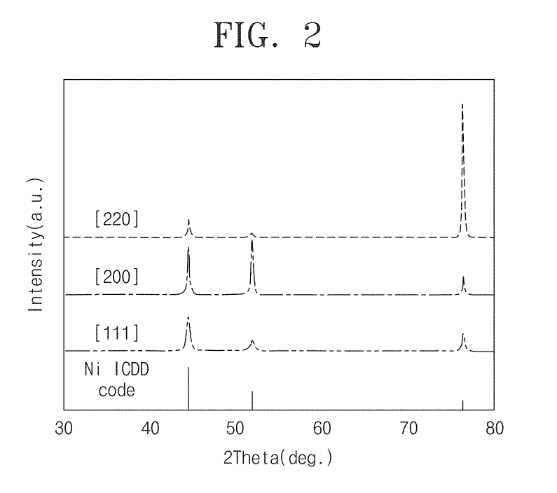

FIG. 2 shows a graph indicating X-ray diffraction (XRD) patterns of nickel nanowire arrays according to an example embodiment of the present disclosure.

Referring to FIG. 2, an XRD pattern indicates a strong signal which indicates a crystalline peak at 20 corresponding to a powder diffraction of nickel. A difference in relative signal intensity between a crystalline peak of a nickel nanowire array and a crystalline peak of nickel powder arranged perpendicularly in an AAO nanotemplate indicates that a nickel nanowire array is more oriented with a specific orientation than randomly arranged nickel powders.

When a precursor is nickel(II) sulfate heptahydrate (NiSO₄.7H₂O) and a buffer solution is ammonium sulfate ((NH₄)₂SO₄), a preferred orientation of a first nickel nanowire array (NiS-As) is organized in a [111] direction.

When the precursor is nickel(II) chloride hexahydrate (NiCl₂.6H₂O) and the buffer solution is boric acid (H₃BO₃), grain growth in a [220] direction is suppressed at the second nickel nanowire (NiCl-B) and a preferred orientation is a [200] direction.

When the precursor is nickel(II) sulfate heptahydrate (NiSO₄.7H₂O) and the buffer solution is boric acid (H₃BO₃), a third nickel nanowire (NiS-B) is aligned in a [220] direction of faced centered cubic (fcc).

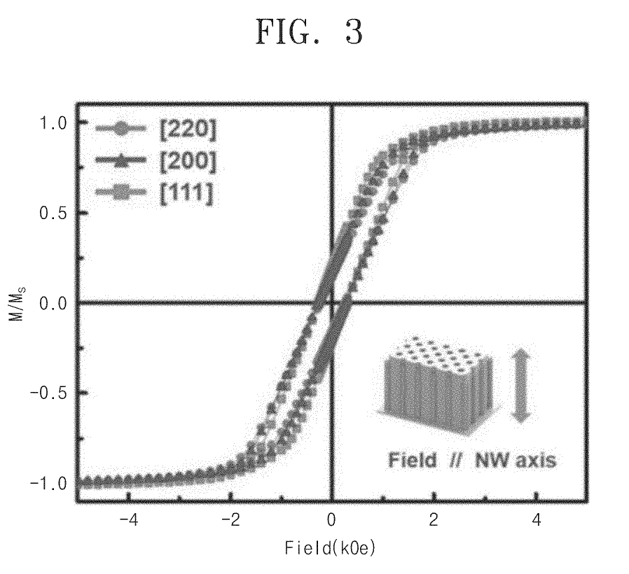

FIG. 3 shows magnetization versus applied magnetic field curves of nickel nanowire arrays according to an example embodiment of the present disclosure.

Referring to FIG. 3, magnetization versus applied magnetic field curves were measured using a vibrating-sample magnetometer (VSM). Magnetic properties of a nickel nanowire array were measured at room temperature under a magnetic field applied parallel to a nanowire axis. The nickel nanowire array has an experimental coercivity within the range between 276 Oe and 244 Oe and has soft magnetic properties. A low coercivity (Hc) and an inclined hysteresis loop are presented by magnetostatic interactions between nickel nanowires buried in an anodized aluminum template.

When a nanowire changes in texture, nanowire arrays have different magnetic susceptibilities. A magnetic susceptibility of each nanowire array shows a similar tendency to magnetocrystalline anisotropy. For example, a magnetic susceptibility increases from 6.15×10⁻⁴ to 8.12×10⁻⁴ as a preferred orientation of a nickel nanowire changes from a [220] direction to a [111] direction that is the magnetization easy direction in fcc structure.

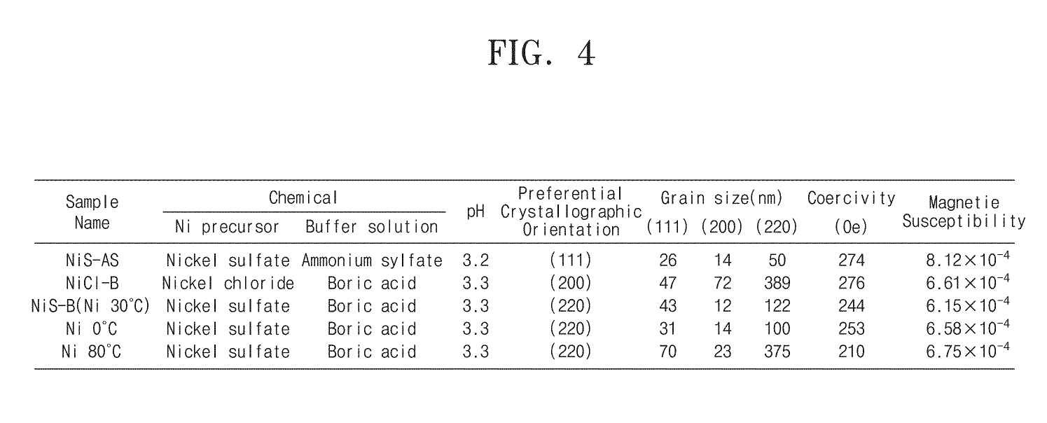

FIG. 4 illustrates characteristics of a nickel nanowire array fabricated under various conditions.

Referring to FIG. 4, a difference of coercivity is observed according to fabrication condition of a nickel nanowire array. However, it is a collective magnetic property affected by various factors such as grain size and defect. Microstructures feature and magnetic properties are shown according to synthesis condition of a nickel nanowire array having different textures.

To investigate a contribution to coercivity variation from the standpoint of a grain size, we synthesized a third nanowire array (NiS-B) having three different grain sizes at temperatures of zero, 30, and 80 degrees Celsius by controlling a plating solution temperature.

The third nanowire array (NiS-B) has a preferred crystallographic orientation in a [220] direction. A mean grain size was calculated using Scherrer's equation. The mean grain size is 100 nm at temperature of zero degree Celsius, 122 nm at temperature of 30 degrees Celsius, and 375 nm at temperature of 80 degrees Celsius. Increase in deposition temperature contributes to increase in grain size.

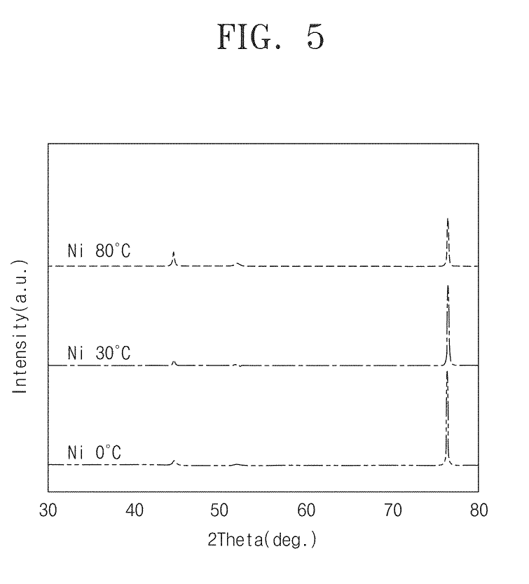

FIG. 5 illustrates X-ray diffraction (XRD) results of a third nickel nanowire array (NiS-B) synthesized at temperatures of zero, 30, and 80 degrees Celsius, respectively.

Referring to FIG. 5, the third nickel nanowire array (NiS-B) has a preferred crystallographic orientation of the same [220] direction at all deposition temperatures.

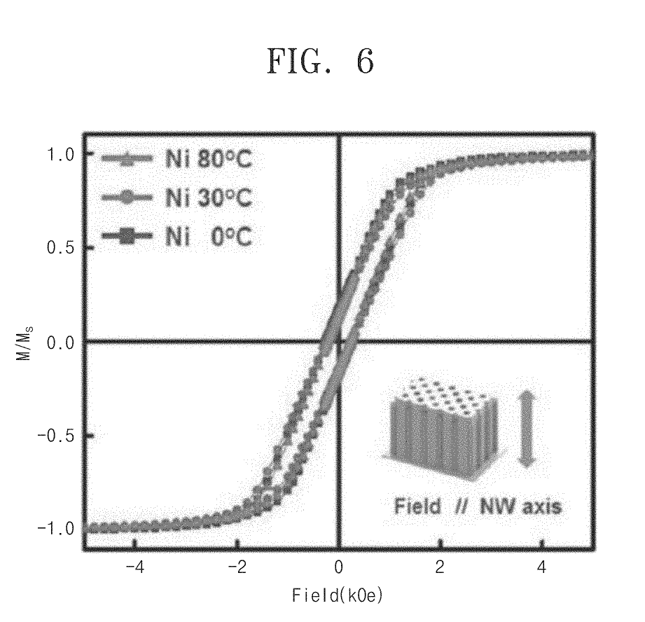

FIG. 6 shows magnetization versus applied magnetic field curves of a third nickel nanowire array (NiS-B) synthesized at temperatures of zero, 30, and 80 degrees Celsius, respectively.

Referring to FIG. 6, a magnetic hysteresis behavior of the third nickel nanowire array (NiS-B) having three different grain sizes is shown. A preferred crystallographic orientation was a [220] direction, and a significant difference of magnetic susceptibility was not observed. According to the hysteresis loop, a magnetization easy axis experimental coercivity is 253, 244, and 210 Oe when a mean grain size is 100, 122, and 375 nm, respectively.

Since the number of defects at a grain boundary decreases as a grain size increases, a coercivity is reduced. Thus, movement of a magnetic domain wall and magnetic momentum switching are relatively less affected due to decrease in internal defects.

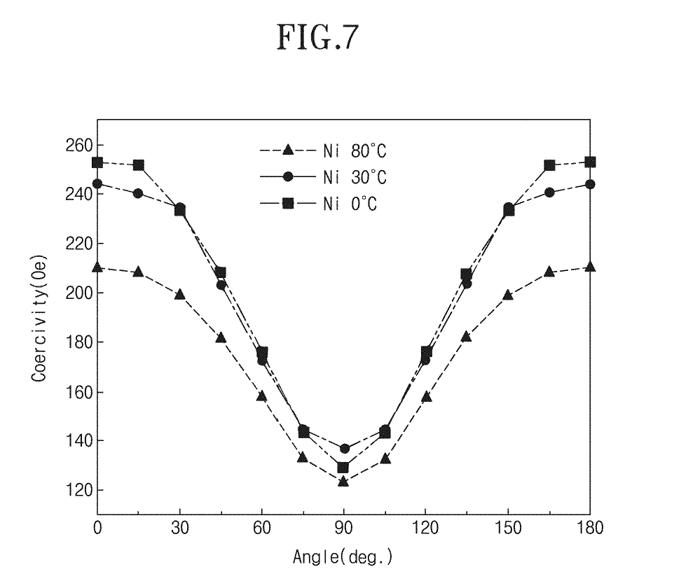

FIG. 7 shows an angle-dependent coercivity of a third nanowire (NiS-B).

Referring to FIG. 7, when an angle between a magnetic field and an extension direction of a nanowire is 90 degrees, a coercivity has a minimum value. The mechanism of magnetic reversal processes is directly related to nucleation and an electric wave of a magnetic domain wall.

Since an experimental coercivity decreases as an angle increases, magnetization reversal processes were most greatly affected by a traverse magnetic domain wall model in which a magnetic moment rotates gradually as a traverse magnetic domain wall propagates. In the case of a nickel nanowire having a relatively small grain (zero and 30 degrees Celsius), a coercivity was rapidly reduced as an angle increased. On the other hand, a coercivity of a nickel nanowire fabricated at temperature of 80 degrees Celsius is gradually reduced as an angle increases.

As described above, a nickel nanowire according to an example embodiment of the present disclosure may have a large specific surface area and adjust mechanical, electric, and magnetic properties in a manner of controlling a crystal direction. Thus, the nickel nanowire may be applied to a micro-electromechanical system which is capable of withstanding a stress, a conducting wire having a low electric resistance, a sensor which reacts more sensitively to an external magnetic field, and the like.

Although the present disclosure and its advantages have been described in detail, it should be understood that various changes, substitutions and alterations can be made herein without departing from the spirit and scope of the disclosure as defined by the following claims.

1. A fabrication method of a nickel nanowire, comprising:
preparing an anodized aluminum oxide or plastic nanotemplate having nanopores and one surface on which platinum (Pt), palladium (Pd), gold (Au), silver (Ag), copper (Cu) or an alloy thereof is deposited as a working electrode;
producing a plating solution consisting of a nickel(II) sulfate heptahydrate (NiSO₄.7H₂O) precursor and an ammonium sulfate ((NH₄)₂SO₄) buffer solution; and
dipping the anodized aluminum oxide or plastic nanotemplate into the plating solution and depositing a nickel nanowire in an electrodeposition process using platinum (Pt) or iridium (Ir) as a counter electrode,
wherein a preferential crystal direction of the nickel nanowire is a [111] direction,
wherein a pH of the plating solution ranges from 3 and 3.5, and
wherein a concentration of the precursor ranges from 1 mM and 50 M, a concentration of the buffer solution ranges from 1 mM and 20 M, and a temperature of the plating solution ranges from zero and 100 degrees Celsius.

2-4. (canceled)

5. A fabrication method of a nickel nanowire, comprising:
obtaining an anodized aluminum oxide or plastic nanotemplate having nanopores and one surface on which platinum (Pt), palladium (Pd), gold (Au), silver (Ag), copper (Cu) or an alloy thereof is deposited as a working electrode;
producing a plating solution which is a mixture of nickel(II) chloride hexahydrate (NiCl₂.6H₂O) as a precursor and boric acid (H₃BO₃) as a buffer solution; and
dipping the anodized aluminum oxide or plastic nanotemplate into the plating solution and depositing a nickel nanowire in an electrodeposition process using platinum (Pt) or iridium (Ir) as a counter electrode,
wherein a preferential crystal direction of the nickel nanowire is a [200] direction,
wherein a pH of the mixture is maintained between 3 and 3.5,
wherein a concentration of the precursor ranges from 1 mM and 50 M, a concentration of the buffer solution ranges from 1 mM and 20 M, and a temperature of the plating solution ranges from zero and 100 degrees Celsius.

6. (canceled)

7. The fabrication method as set forth in claim 1, wherein a mean diameter of the pore of the anodized aluminum oxide or plastic nanotemplate is between 5 and 50 nm.
